(19) United States
(12) Patent Application Publication
(10) Pub. No.: US 2016/0126957 A1
(43) Pub. Date: May 5, 2016

(54) HAND-ACTIVATED COUNTING DEVICE

(71) Applicants: Fu Tai Hua Industry (Shenzhen) Co., Ltd., Shenzhen (CN); Hon Hai Precision Industry Co., Ltd., New Taipei (TW)

(72) Inventor: CHUAN WANG, Shenzhen (CN)

(21) Appl. No.: 14/576,518

(22) Filed: Dec. 19, 2014

(30) Foreign Application Priority Data
Nov. 4, 2014 (CN) 201410610113.3

(51) Int. Cl. H03K 21/02; H03K 21/18

(52) U.S. Cl. CPC H03K 21/02; H03K 21/18

(57) ABSTRACT

A hand-activated counting device includes a pressing module having an elastic assembly and a counting module coupled to the pressing module. The elastic assembly includes a first deformable elastic membrane with a first connecting portion, a second deformable elastic membrane with a second connecting portion, and an insulating element. The counting module includes a housing, a circuit board supported by the housing, a counter, a power supply, and a display. The first deformable elastic membrane is positioned opposite the second deformable elastic membrane with the insulating element separating the first deformable elastic membrane from the second deformable elastic membrane. The power supply is electronically connected to the display and electronically connected to the counter by the elastic assembly. The first connecting portion is coupled to a first contact of the counter and the second connecting portion is coupled to a second contact of the counter.

### FIELD

The disclosure generally relates to counting devices, and particularly to a hand-activated counting device.

### BACKGROUND

In modern society, people feel more and more pressure from work and study. Therefore, people need to relieve their pressure in time for health.

### BRIEF DESCRIPTION OF THE DRAWINGS

Implementations of the present technology will now be described, by way of example only, with reference to the attached figures.

FIG. 1 is an exploded view of a hand-activated counting device, according to an exemplary embodiment.

FIG. 2 is similar to FIG. 1 but shown from another angle.

FIG. 3 is a partial, isometric view of the hand-activated counting device of FIG. 1.

FIG. 4 is an assembled, isometric view of the hand-activated counting device of FIG. 1.

FIG. 5 is a cross-sectional view of the hand-activated counting device of FIG. 4 taken along a line V-V.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

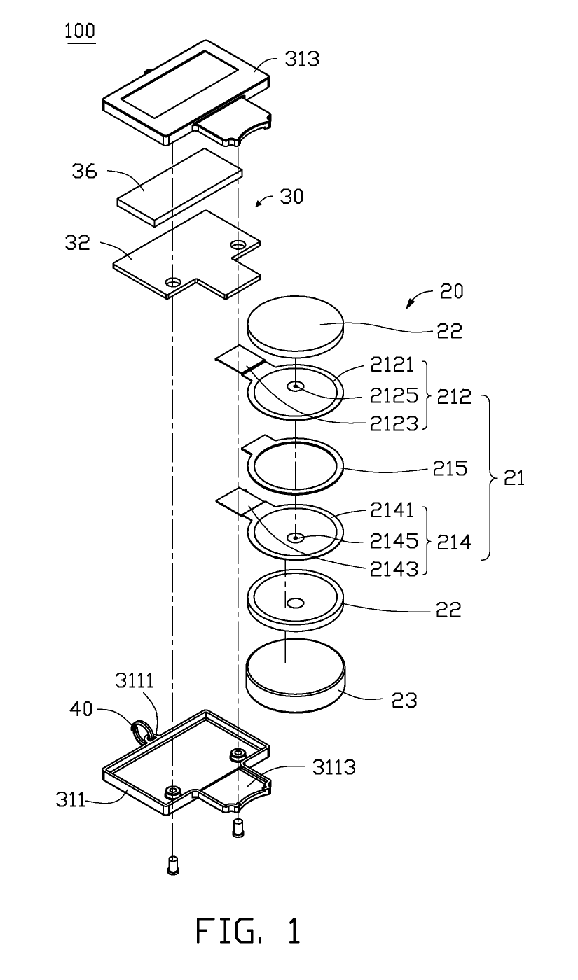

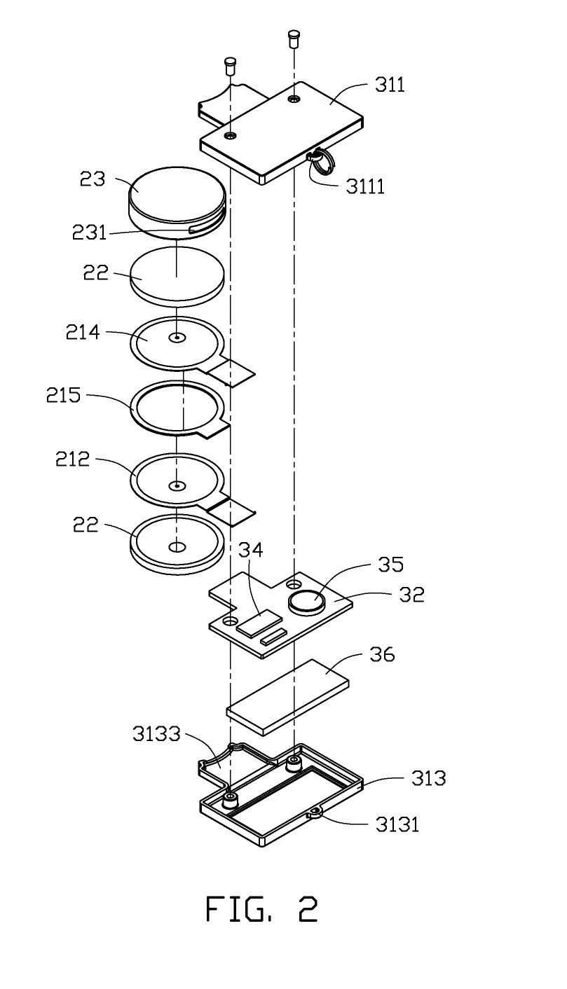

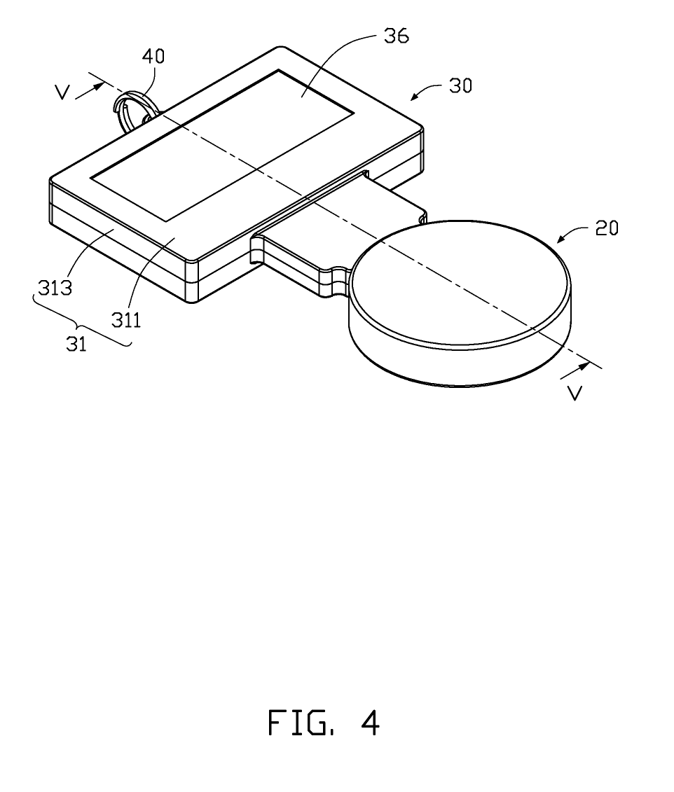

FIG. 1 is an exploded view of a hand-activated counting device 100, according to an exemplary embodiment. The hand-activated counting device 100 includes a pressing module 20 and a counting module 30 (shown in FIG. 4) electrically connected to the pressing module 20. FIG. 2 shows that the pressing module 20 includes an elastic assembly 21, a filler 22, and a case 23. The elastic assembly 21 is received in the case 23. The filler 22 is filled between the elastic assembly 21 and the case 23.

The elastic assembly 21 includes a first deformable elastic membrane 212, a second deformable elastic membrane 214, and an insulating element 215.

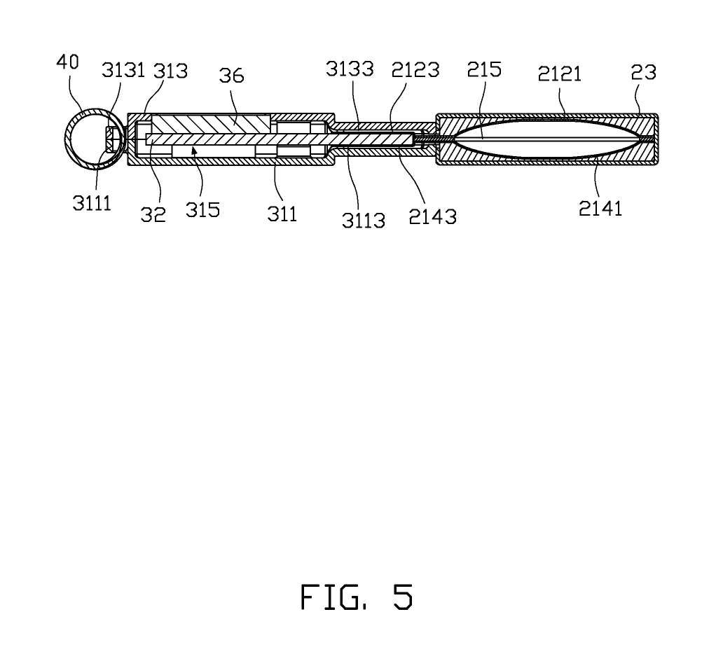

The first deformable elastic membrane 212 includes a first elastic portion 2121 and a first connecting portion 2123. In this exemplary embodiment, the first elastic portion 2121 is substantially convex (see FIG. 5). A first exhaust hole 2125 is defined in a substantial center portion of the first main portion 2121. The first connecting portion 2123 is substantially a strip extended from an edge of the first elastic portion 2121.

The second deformable elastic membrane 214 is substantially similar to the first deformable elastic membrane 212 and includes a second elastic portion 2141 and a second connecting portion 2143. A second exhaust hole 2145 is defined in a substantial center portion of the second elastic portion 2141. The second connecting portion 2143 is substantially a strip extended from an edge of the second elastic portion 2141. The difference between the first deformable elastic membrane 212 and the second deformable elastic membrane 214 is that the second elastic portion 2141 is substantially concave (see FIG. 5).

The insulating element 215 is substantially circular and corresponds to the first elastic portion 2121 and the second elastic portion 2141. The insulating element 215 is sandwiched between the first elastic portion 2121 and the second elastic portion 2141 to separate the first deformable elastic membrane 212 and the second deformable elastic membrane 214 from each other. The first elastic portion 2121 and the second elastic portion 2141 can be pressed and deformed to contact with each other.

In this exemplary embodiment, the case 23 is substantially cubic and made of elastic material. An opening 231 is defined in one side of the case 23. The elastic assembly 21 is received in the case 23 with the first connecting portion 2123 and the second connecting portion 2143 exposed from the case 23 via the opening 231. The case 23 can be pressed to deform the first deformable elastic membrane 212 and the second deformable elastic membrane 214 inside the case 23.

The filler 22 is filled between the elastic assembly 21 and the case 23 (i.e. the first deformable elastic membrane 212 and the case 23, and the second deformable elastic membrane 214 and the case 23). In this exemplary embodiment, the filler 22 is made of foam and configured for improving the tactile effects of pressing the case 23.

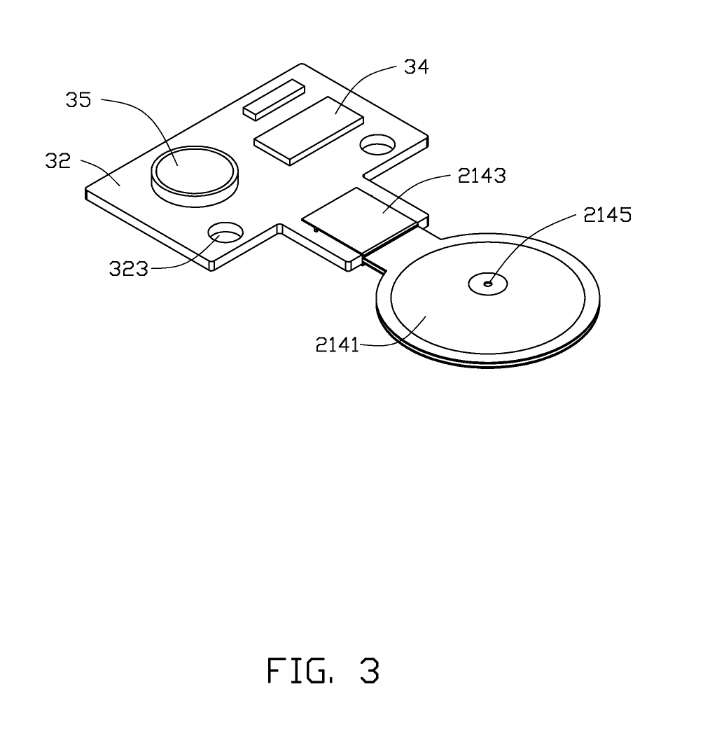

FIGS. 3 and 4 show that the counting module 30 includes a housing 31, a circuit board 32, a counter 34, a power supply 35, and a display 36.

The housing 31 includes a base 311 and a cover 313. The cover 313 covers the base 311 and cooperatively forms a receiving chamber 315 with the base 311. The circuit board 32, the counter 34, the power supply 35, and the display 36 are received in the receiving chamber 315.

The base 311 includes a first protruding portion 3111 and a first extending portion 3113. The first protruding portion 3111 is substantially ring-shaped and protrudes from one side of the base 311. The first extending portion 3113 is extended from another side of the base 311 opposite to the first protruding portion 3111.

The cover 313 is substantially similar to the base 311 and includes a second protruding portion 3131 and a second extending portion 3133 corresponding to the first protruding portion 3111 and the first extending portion 3131, respectively. The second protruding portion 3131 is substantially ring-shaped and protruding from one side of the cover 313. The second extending portion 3133 extends from the side of the cover 313 opposite to the second protruding portion 3131.

The counter 34 and the power supply 35 are positioned on the circuit board 32. The power supply 35 is configured for providing electric power to the counter 34 and the display 36. The power supply 35 is electronically connected to the display 36 and electronically connected to the counter 34 via the elastic assembly 21. The display 36 is positioned on the cover 313. The display 36 is electronically connected to the counter 34 and configured for displaying a number counted by the counter 34.

In assembly, the first elastic portion 2121 and the second elastic portion 2141 are attached to two sides of the insulating element 215, respectively, so that the first connecting portion 2123 and the second connecting portion 2143 are spaced from each other. The elastic assembly 21 is received in the case 23 with the first connecting portion 2123 and the second connecting portion 2143 exposed from the case 23 via the opening 231 and the filler 22 filled between the elastic assembly 21 and the case 23.

The first connecting portion 2123 and the second connecting portion 2143 outside the case 23 are positioned at two sides of the circuit board 32 and electronically connected to two contacts (not shown) of the counter 34. The cover 313 covers the base 311 with the first protruding portion 3111 and the first extending portion 3113 aligning with the second protruding portion 3113 and the second extending portion 3133, respectively. The circuit board 32 assembled with the power supply 35 and the counter 34 is received in the case 311. The first connecting portion 2123 and the second connecting portion 2143 are received in and latched by the first and second extending portion 3113, 3133. Therefore, the hand-activated counting device 100 is assembled.

Because the first connecting portion 2123 is spaced from the second connecting portion 2143, the contacts of the counter 34 are disconnected from each other and the counter 34 is inactivated. In use, the case 23 is pressed so that air between the first elastic portion 2121 and the second elastic portion 2141 are exhausted from the first and second exhaust holes 2125, 2145 and the first elastic portion 2121 and the second elastic portion 2141 are deformed to contact with each other. Thus, the first connecting portion 2123 and the second connecting portion 2143 are electrically connected to each other. The counter 34 is electronically connected to the power supply 35 so that the counter 34 is activated and starts to count. When the case 23 is released, the first elastic portion 2121 is separated from the second elastic portion 2141 and the first connecting portion 2123 and the second connecting portion 2143 is electrically disconnected from each other. Thus, the counter 34 is electronically disconnected from the power supply 35 so that the counter 34 is inactivated and stops counting; that is the counter 34 counts one time once the case 23 is pressed. The number counted by the counter 34 denotes a number that the case 23 is pressed. The display 36 also displays the number. Therefore, the hand-activated counting device 100 can be repeatedly pressed and released by users to relieve pressure.

In other exemplary embodiments, the electronic device 100 further includes a hanging ring 40. The hanging ring 40 is extended through the first protruding portion 3111 and the second protruding portion 3131. The hanging ring 40 is configured to conveniently carry the hand-activated counting device 100.

In addition, the first and second exhaust holes 2141, 2145 can be omitted. When the case 23 is pressed, the air between the first elastic portion 2121 and the second elastic portion 2141 are exhausted from a gap between the first deformable elastic membrane 212 and the second deformable elastic membrane 214.

The hand-activated counting device 100 has a relatively small volume making it portable so that users can freely release pressure anytime and anywhere. In addition, the counter 34 can count the number of presses of the user of the hand-activated counting device 10.

It is to be understood, however, that even through numerous characteristics and advantages of the present disclosure have been set forth in the foregoing description, together with details of assembly and function, the disclosure is illustrative only, and changes may be made in the details, especially in the matters of shape, size, and arrangement of parts within the principles of the disclosure to the full extent indicated by the broad general meaning of the terms in which the appended claims are expressed.

What is claimed is:

1. A hand-activated counting device comprising:
a pressing module, the pressing module comprising an elastic assembly, the elastic assembly comprising:
a first deformable elastic membrane with a first connecting portion;
a second deformable elastic membrane with a second connecting portion; and
an insulating element; and
a counting module coupled to the pressing module, the counting module having:
a housing;
a circuit board supported by the housing;
a counter;
a power supply; and
a display;
wherein, the first deformable elastic membrane is positioned opposite the second deformable elastic membrane with the insulating element separating the first deformable elastic membrane from the second deformable elastic membrane;
wherein, the power supply is electronically connected to the display and connected to the counter by the elastic assembly, with the display electronically connected to the counter to display a number counted by the counter;
wherein, the first connecting portion is coupled to a first contact of the counter and the second connecting portion is coupled to a second contact of the counter; and
wherein, when the first deformable elastic membrane and the second deformable elastic membrane are deformed moving the first deformable elastic membrane and the second deformable elastic membrane toward each other, the first connecting portion becomes in contact with the second connecting contact activating the counter.

2. The hand-activated counting device of claim 1, wherein the first deformable elastic membrane comprises a first elastic portion and a first connecting portion extended from an edge of the first elastic portion; the second deformable elastic membrane comprises a second elastic portion and a second connecting portion extended from an edge of the second elastic portion; the first elastic portion and the second elastic portion are attached to the two sides of the insulating element, the first and second connecting portions are electrically connected to the counting module, the first and second elastic portions are deformed to contact with each other when the elastic assembly is pressed.

3. The hand-activated counting device of claim 2, wherein the first elastic portion defines a first exhaust hole, the second elastic portion defines a second exhaust hole, the first and second exhaust holes are configured for air between the first and second deformable elastic membranes exhausted therefrom when the elastic assembly is pressed.

4. The hand-activated counting device of claim 2, wherein the first deformable elastic membrane is substantially convex; the second deformable elastic membrane is substantially concave.

5. The hand-activated counting device of claim 3, further comprising a case, wherein the elastic assembly is received in the case.

6. The hand-activated counting device of claim 5, further comprising a filler, wherein the filler is filled between the elastic assembly and the case.

7. The hand-activated counting device of claim 2, wherein the counting module comprises a housing and a counter; the housing comprises a base and a cover, the cover covers the base to form a receiving chamber with the base; the counter is received in the housing.

8. The hand-activated counting device of claim 7, further comprising a hinging ring, wherein the base comprises a first protruding portion protruding from one side of the base, the cover comprises a second protruding portion protruding from one side of the cover, the hinging ring is extended through the first and second protruding portions.

9. The hand-activated counting device of claim 8, wherein the base further comprises a first extending portion extended from another side of the base, the cover further comprises a second extending portion extended from another side of the cover; the first and second connecting portions are received between and latched by the first and second extending portions.

10. A hand-activated counting device comprising:
an elastic assembly; and
a counter electrically connected to an elastic assembly; wherein the counter is activated to count by pressing and releasing the elastic assembly.

11. The hand-activated counting device of claim 10, wherein the elastic assembly comprises a first deformable elastic membrane, a second deformable elastic membrane, and an insulating element; the first and second deformable elastic membranes are attached to two sides of the insulating element and spaced from each other and electrically connected to the counter.

12. The hand-activated counting device of claim 11, wherein the first deformable elastic membrane comprises a first elastic portion and a first connecting portion extended from an edge of the first elastic portion; the second deformable elastic membrane comprises a second elastic portion and a second connecting portion extended from an edge of the second elastic portion; the first elastic portion and the second elastic portion are attached to the two sides of the insulating element, the first and second connecting portions are electrically connected to the counting module, the first and second elastic portions are deformed to contact with each other when the elastic assembly is pressed.

13. The hand-activated counting device of claim 12, wherein the first elastic portion defines a first exhaust hole, the second elastic portion defines a second exhaust hole, the first and second exhaust holes are configured for air between the first and second deformable elastic membranes exhausted therefrom when the elastic assembly is pressed.

14. The hand-activated counting device of claim 12, wherein the first deformable elastic membrane is substantially convex; the second deformable elastic membrane is substantially concave.

15. The hand-activated counting device of claim 13, further comprising a case, wherein the elastic assembly is received in the case.

16. The hand-activated counting device of claim 15, further comprising a filler, wherein the filler is filled between the elastic assembly and the case.

17. The hand-activated counting device of claim 12, further comprises a housing; wherein the housing comprises a base and a cover, the cover covers the base to form a receiving chamber with the base; the counter is received in the housing.

18. The hand-activated counting device of claim 17, further comprising a hinging ring, wherein the base comprises a first protruding portion protruding from one side of the base, the cover comprises a second protruding portion protruding from one side of the cover, the hinging ring is extended through the first and second protruding portions.

19. The hand-activated counting device of claim 18, wherein the base further comprises a first extending portion extended from another side of the base, the cover further comprises a second extending portion extended from another side of the cover; the first and second connecting portions are received between and latched by the first and second extending portions.
